(19) United States
(12) Patent Application Publication
(10) Pub. No.: US 2014/0167795 A1
(43) Pub. Date: Jun. 19, 2014

(54) ACTIVE FEEDBACK SILICON FAILURE ANALYSIS DIE TEMPERATURE CONTROL SYSTEM

(71) Applicant: TEXAS INSTRUMENTS INCORPORATION, Dallas, TX (US)

(72) Inventors: Joseph S. Mayfield, Cypress, TX (US); Chad R. Turner, Lewisville, TX (US); Nolan B. Riley, Rosharon, TX (US)

(73) Assignee: TEXAS INSTRUMENTS INCORPORATED, Dallas, TX (US)

(21) Appl. No.: 13/714,740

(22) Filed: Dec. 14, 2012

(51) Int. Cl. G01R 31/28

(52) U.S. Cl. CPC G01R 31/2874
USPC 324/750.03

(57) ABSTRACT

Fault analysis of high power integrated circuits face thermal management challenges. This invention employs thermal diodes incorporated in the device undergoing fault analysis, and a closed loop microprocessor controlled feedback system for thermal control during test and fault analysis.

### TECHNICAL FIELD OF THE INVENTION

The technical field of this invention is integrated circuit failure analysis.

### BACKGROUND OF THE INVENTION

This invention controls the temperature of a self-heating, high power device during failure analysis.

### SUMMARY OF THE INVENTION

This invention places a microcontroller on the device under test (DUT) load board or on an external enclosure coupled to the DUT load board. This microcontroller reads the DUT's thermal diode. The microcontroller controls a metering valve connected to an existing cooling fluid line (such as liquid nitrogen (LN₂) or compressed air) based on the reading. Based on the DUT's internal die temperature, the microcontroller will open or close the metering valve to regulate the device temperature. The cooling fluid will be injected to the top of the device with a special manifold system incorporated into the test socket designed to create cooling gas flow over much of the DUT top's surface area without blocking the access to the top of the DUT.

### BRIEF DESCRIPTION OF THE DRAWINGS

These and other aspects of this invention are illustrated in the drawings, in which:

FIG. 1 is a schematic illustration of the electronics of this invention;

FIG. 2 illustrates the Proportional Integral Derivative (PID) feedback control system of the microcontroller in schematic form;

FIG. 3 is a simplified schematic diagram of the solenoid drive circuit; and

FIG. 4 is an illustration of the open top lid of the invention.

### DETAILED DESCRIPTION OF PREFERRED EMBODIMENTS

This invention addresses the problem of doing failure analysis on high power devices. During failure analysis, the top surface of the die must be exposed and accessible to the test apparatus, negating the use of conventional temperature control means.

The DUTs suitable for this invention have one or more on-die thermal diodes. This invention uses the DUT thermal diodes for real time on-die temperature measurement. The system uses an I²C communications chip (on-board the tester adapter board) to read the DUT thermal diode(s). An 8-bit microcontroller running code to measure the temperature uses this information to calculate a third order control system response. This microcontroller sends a variable duty-cycled pulse to LN₂ solenoid drive circuitry. The LN₂ is directed through a cryogenic hose into an open lid covering the DUT. The lid has an interface system to deliver LN₂ bursts around the exposed DUT without blocking the top surface of the die.

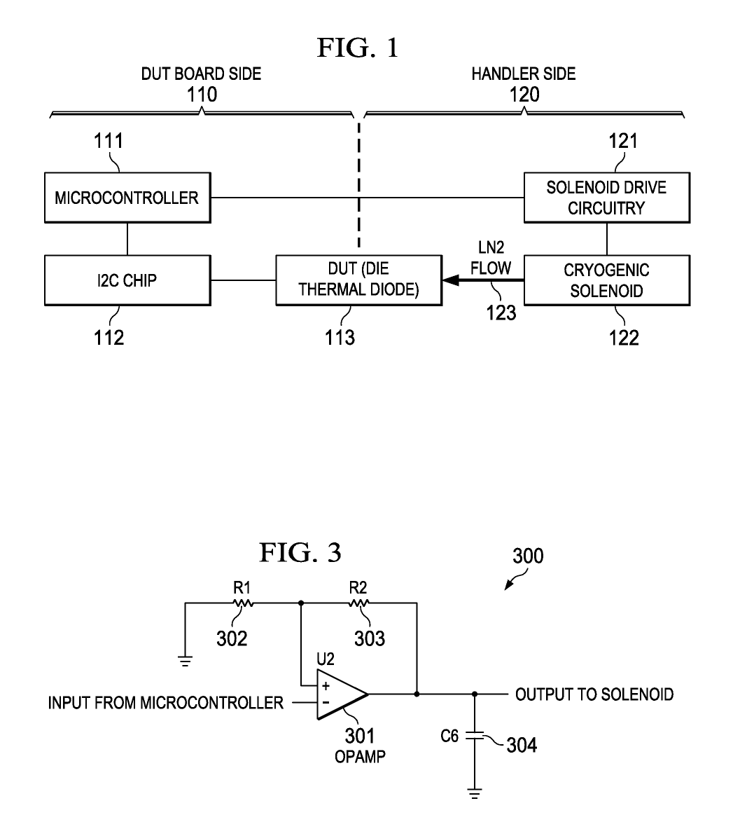

FIG. 1 is a schematic illustration of the electronics of this invention. This invention includes parts on the DUT board side 110 and on the handler side 120. DUT board side 110 includes microcontroller 111, I²C chip 112 and plural DUT wafers 113. Handler side 120 includes solenoid drive circuitry 121, cryogenic solenoid 122 and LN₂ flow 123. Thermo diodes on wafers 113 supply signals corresponding to their current temperatures. I²C chip 112 conditions these signals for use by microcontroller 111. In this embodiment I²C chip 112 is an LM9534 which is more fully explained below. Microcontroller 111 produces a solenoid drive signal for temperature control. A communications interface transfers signals from microcontroller 111 to solenoid drive circuitry 121. Solenoid drive circuitry 121 controls the opening and closing of solenoid 122. This controls a valve controlling LN₂ flow 123. LN₂ flow 123 influences the temperature measured by the thermo diodes of wafers 113. Microcontroller 111 operates upon the measured temperature to control solenoid 122 for thermal control during failure analysis of the DUT.

Prior art to monitor DUT temperature during test was by reading a thermal diode during the test flow. This function uses the ideality factor algorithm (equation (1) below) to calculate temperature by forcing two different currents through the thermal diode and reading the voltage results from each forced current. The force currents typically differ by a factor of 10:1. The measured temperature T_{C} is given by:

$${T}_{C} = \frac{( {V}_{H} - {V}_{L} )}{1.985 \times {10}^{- 4} \times n} - 273.15 \qquad ( 1 )$$

where: V_{H} is the voltage reading during the higher force current; V_{L} is the voltage reading during the lower force current; and n is an ideality factor of the thermal diode.

There is a problem with this prior art method. With this prior art method temperature readings cannot be made in real time. In addition each reading causes an increase in test time. The prior art typically executes the thermal diode read function either before a test function or after the test function. As a result the prior art measurement is not an accurate temperature reading during pattern execution. Thus there is a need for an external method of reading of the thermal diode that does not use the test program.

This invention is a solution to this problem. In this invention circuits are installed on the tester adapter boards to provide real-time DUT temperature readings. This invention preferably uses a National Semiconductor LM95234 device to read the on-chip thermal diodes. The LM95234 preferably is given direct access to the DUT thermal diode pins and is connected to our microcontroller via a Molex connector. The tester adapter boards preferably also have a Texas Instruments TMP100 (temperature monitor) mounted on the DUT side 110. This temperature monitor is accessed by microcontroller 111, allowing measurement of the handler ambient temperature.

Microcontroller 111 controls the DUT temperature. Microcontroller 111 monitors the device temperature in real-time and controls a cooling device. This invention preferably includes an Arduino ATMEGA328 microcontroller because of its small size, low cost and ease of code development. The Arduino microcontroller includes the ability to communicate to other devices using an I²C link. In the preferred embodiment of this invention the tester adapter board uses a remote diode temperature sensor IC that communicates the temperature readings of one or more thermal diodes through an I²C channel. With this connected to our microcontroller, we have the ability to read the device temperature of multiple sites as well as the top and bottom side temperature of the tester adapter board. These temperature readings preferably are collected real-time and stored in a vector format for further analysis. The microcontroller controls the self heating of DUT by pulsing cryogenic solenoid 122 injecting boiled LN₂ gas directly on the device lid. Early experiments showed the need to develop a smart algorithm to calculate the LN₂ solenoid pulse duration in order to keep DUT die temperatures within the specified guard band.

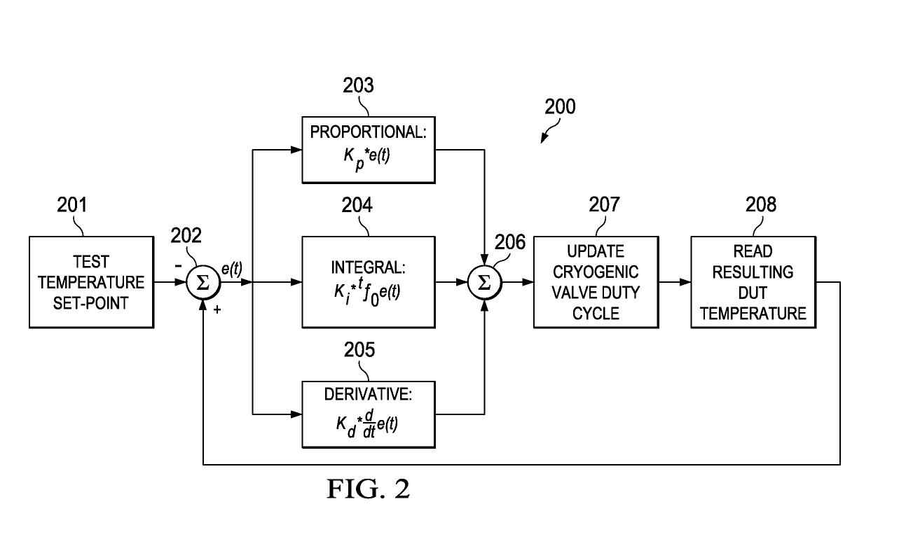

FIG. 2 illustrates the system software-based Proportional-Integral-Derivative (PID) feedback control system 200 in schematic form. Control system 200 receives an independent input 201 determining the desired temperature. Summer 202 subtracts a actual measured temperature from sensor 208 from the step point temperature generating an error signal e(t). According to the preferred embodiment of this invention the cryogenic valve is operated on a one-second period Pulse Width Modulation (PWM) scheme. Microcontroller 111 sets the duty cycle of the PWM by PID control. In order to achieve optimal temperature control, special consideration had to be given to this software implementation.

Block 203 computes the proportional aspect of the PID from a product of error signal e(t) and a proportional constant K_{P} (K_{P}*e(t)). This component increases the PWM duty cycle proportional to the error signal.

Block 204 computes the Integral factor. This is the product of an integral constant K_{I} by an integral of the error e(t)

$$( {K}_{I} * {\int }_{0}^{t} e ( t ) ) .$$

In a discrete sampled system this integral is computed by multiplying the time elapsed since the last calculation by the error signal e(t). This portion of the PID control helps to eliminate any steady-state error in the DUT test temperature by summing the instantaneous error over time.

Block 205 computes the Derivative term. This is the product of a derivative constant K_{D} and the derivative of the error signal

$$( {K}_{D} * \frac{d}{d t} e ( t ) ) .$$

In a discrete sampled system this derivative is computed by subtracting the error from the previous calculation by the present error and dividing this difference by the time elapsed between the two readings. This portion of the control system helps to control over-shoot and maintain system stability.

Each of the three individual PID terms has an associated constant that is used to fine-tune the response of the system (K_{P}, K_{I}, K_{D}). The CTCS uses these constants to guard against system over-shoot. Summer 206 sums these three terms of the PID control calculation generating am overall PID result. Block 207 translates this PID result to a PWM duty cycle by dividing by a maxoutput constant. This constant gives yet another tool that can be used to adjust system response. This signal controls the cryogenic solenoid. The cryogenic solenoid controls the rate of supply of LN₂ to the DUT. This in turn controls the DUT temperature. Sensor 208 measures the DUT temperature and completes the feedback loop.

The preferred cryogenic solenoid is a 24 Volt cryogenic solenoid specially manufactured for LN₂ service applications by GEMS Sensors and Controls. The specified drive current necessary to close this solenoid is 3 Amperes. Since the microcontroller drive current is only specified in the mA range, This invention includes a circuit to drive the solenoid, using a Texas Instruments OPA548 operational amplifier.

FIG. 3 is a simplified schematic diagram of this solenoid drive circuit 300. Operational amplifier 301 receives an input from the microcontroller on its inverting input. The non-inverting input of operational amplifier 301 is connected to the center node of a voltage divider formed of resistors 302 and 303. In the preferred embodiment illustrated in FIG. 3, resistor 302 is 1 KΩ and resistor 303 4 KΩ. The voltage divider is connected between the output of operational amplifier 301 and ground. The output of operational amplifier 301 also connects to one terminal of capacitor 304, whose other terminal is connected to ground. As illustrated in FIG. 3 capacitor 304 is preferably 220 μf.

This circuit is powered using an external power supply. The exemplary values of resistors 302 and 303 provide 5:1 non-inverting gain. This gain was selected to match the 22 V input requirement of the selected solenoid.

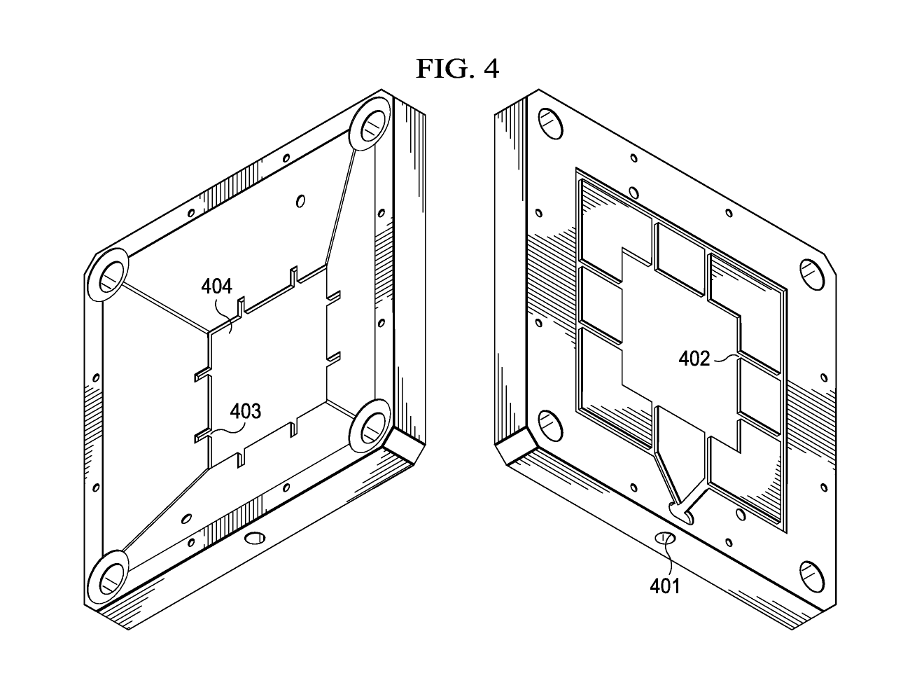

FIG. 4 shows the lid used by this invention. Inlet port 401 is connected to the cooling medium source. A number of gas channels 402 distribute the cooling medium around the circumference of top opening 404, and deliver the cooling medium to gas injection ports 403. The geometry of the lid and the injection ports is such that the cooling medium will flow across the surface of the DUT.

What is claimed is:

1. An integrated circuit test handler for a device undergoing failure analysis having at least one thermal diode comprising:
a device under test board adapted to receive a integrated circuit for test;
an electrical connector for coupling to said at least one thermal diode on the integrated circuit;
a microcontroller connected to said electrical connector programmed to
compare a temperature corresponding to signals from the at least one thermal diode on the integrated circuit to a temperature set point thereby generating an error signal, and
compute a solenoid drive signal from said error signal;
a source of cooling fluid;
a valve coupled to the source of cooling fluid, said valve having an open state supplying cooling fluid to bathe the integrated circuit and a closed state excluding cooling fluid from the integrated circuit; and
a solenoid receiving said solenoid drive signal and controlling the open/closed state of said valve.

2. The integrated circuit test handler of claim 1, wherein:
said cooling fluid is boiled liquid nitrogen.

3. The integrated circuit test handler of claim 1, wherein:
said cooling fluid is compressed air.

4. The integrated circuit test handler of claim 1, further comprising:
an I²C interface connected by said electrical connector to said at least one thermal diode generating a signal suitable for reading by said microcontroller.

5. The integrated circuit test handler of claim 4, further comprising:
said I²C interface is mounted on said device under test board.

6. The integrated circuit test handler of claim 5, further comprising:
said microcontroller is mounted on a circuit board separate from said device under test board.

7. The integrated circuit test handler of claim 1, wherein:
said microcontroller is programmed to compute a solenoid drive signal by
forming a Proportional-Integral-Derivative function of said error signal, and
converting said Proportional-Integral-Derivative function into a pulse width modulated drive function for said solenoid.

8. The integrated circuit test handler of claim 1, further comprising:
a solenoid drive circuit connected to said microcontroller receiving said pulse width modulated drive function and generating an amplified solenoid drive function suitable for controlling said solenoid.

9. The integrated circuit test handler of claim 8, wherein:
said solenoid drive circuit includes an operational amplifier.

10. The integrated circuit test handler of claim 1, further comprising:
a lid with a central opening covering said integrated circuit and exposing the surface of said integrated circuit;
an inlet port on said lid operable to receive said cooling fluid;
a plurality of gas channels operable to evenly distribute said cooling fluid around the circumference of said lid;
a plurality of gas injection ports connected to said gas channels operable to distribute the cooling fluid to the surface of said integrated circuit.
